(19) United States
(12) Patent Application Publication
(10) Pub. No.: US 2019/0334499 A1
(43) Pub. Date: Oct. 31, 2019

(54) ELASTIC WAVE DEVICE

(71) Applicant: Murata Manufacturing Co., Ltd., Nagaokakyo-shi (JP)

(72) Inventors: Takuya KOYANAGI, Nagaokakyo-shi (JP); Daisuke TAMAZAKI, Nagaokakyo-shi (JP)

(21) Appl. No.: 16/505,935

(22) Filed: Jul. 9, 2019

Related U.S. Application Data
(63) Continuation of application No. PCT/JP2017/044347, filed on Dec. 11, 2017.

(30) Foreign Application Priority Data
Jan. 10, 2017 (JP) 2017-001886

(51) Int. Cl. H03H 9/02; H03H 9/145

(52) U.S. Cl. CPC H03H 9/02858; H03H 9/1457; H03H 9/1452

(57) ABSTRACT

An elastic wave device includes an IDT electrode and a first dielectric layer provided on a piezoelectric substrate. An intersection region where first electrode fingers and second electrode fingers in the IDT electrode overlap each other as viewed from an elastic wave propagation direction includes a center region, a first edge region located on one side of the center region in a direction in which the first electrode fingers and the second electrode fingers extend, and a second edge region located on the other side of the center region in the direction in which the first electrode fingers and the second electrode fingers extend. A mass addition film laminated on the first dielectric layer includes portions of at least two thicknesses.

### CROSS REFERENCE TO RELATED APPLICATIONS

This application claims the benefit of priority to Japanese Patent Application No. 2017-001886 filed on Jan. 10, 2017 and is a Continuation Application of PCT Application No. PCT/JP2017/044347 filed on Dec. 11, 2017. The entire contents of each application are hereby incorporated herein by reference.

### BACKGROUND OF THE INVENTION

### 1. Field of the Invention

The present invention relates to an elastic wave device including an IDT electrode and a dielectric layer that are laminated on a piezoelectric substrate.

### 2. Description of the Related Art

Elastic wave devices that use the piston mode to reduce or prevent the occurrence of transverse mode ripples have been known. In such an elastic wave device using the piston mode, an intersection region in an IDT electrode includes a center region and edge regions on both sides of the center region. The intersection region is a region where electrode fingers connected to different potentials overlap with each other as viewed from the elastic wave propagation direction. By making the acoustic velocity in the edge regions lower than that in the center region, the piston mode is provided.

In the elastic wave device disclosed in Japanese Unexamined Patent Application Publication No. 2012-186808, a dielectric layer made of, for example, silicon oxide is laminated to cover an IDT electrode. In the dielectric layer, a metal strip is provided over the edge regions. This metal strip is an adequate metal layer for changing an acoustic wave velocity. A second dielectric layer is further provided on the dielectric layer in a region between the inner edges of opposite busbars. Over the center region, a third dielectric layer is further laminated on the second dielectric layer. The third dielectric layer is an adequate dielectric layer for changing an acoustic wave velocity. The adequate metal layer and dielectric layer for changing an acoustic wave velocity or the combination thereof makes the acoustic velocity in the center region, the acoustic velocity in the edge regions, and the acoustic velocity in an outer side region of the edge regions different from each other such that the velocity in the edge regions becomes lower than that in the center region.

In the elastic wave device disclosed in Japanese Unexamined Patent Application Publication No. 2012-186808, by providing a plurality of layers, the differences in an acoustic velocity are made in the center region, the edge regions, and the outer side region of the edge regions. Accordingly, the adjustment for precisely making an acoustic velocity difference is difficult.

### SUMMARY OF THE INVENTION

Preferred embodiments of the present invention provide elastic wave devices that are each able to easily provide a difference in an acoustic velocity in a center region and edge regions in an IDT electrode.

An elastic wave device according to a preferred embodiment of the present invention includes a piezoelectric substrate, an IDT electrode provided on the piezoelectric substrate, a first dielectric layer provided to cover the IDT electrode, and a mass addition film that is provided on the first dielectric layer and includes portions of at least two thicknesses. The IDT electrode includes a first busbar, a second busbar opposite the first busbar, a plurality of first electrode fingers each including one end electrically connected to the first busbar, and a plurality of second electrode fingers each including one end electrically connected to the second busbar. The first electrode fingers and the second electrode fingers are interdigitated with each other. An intersection region where the first electrode fingers and the second electrode fingers overlap each other as viewed from an elastic wave propagation direction includes a center region, a first edge region located on one side of the center region in a direction in which the first electrode fingers and the second electrode fingers extend, and a second edge region located on the other side of the center region in the direction in which the first electrode fingers and the second electrode fingers extend.

In an elastic wave device according to a preferred embodiment of the present invention, a thickness of the mass addition film in portions corresponding to the first edge region and the second edge region is larger than a thickness of the mass addition film in a portion corresponding to the center region.

In an elastic wave device according to a preferred embodiment of the present invention, the mass addition film extends to an outer side region of the first edge region and an outer side region of the second edge region in the direction in which the first electrode fingers and the second electrode fingers extend. A thickness of the mass addition film over the outer side region of the first edge region and the outer side region of the second edge region is smaller than a thickness of the mass addition film over the first edge region and the second edge region. In this case, high acoustic velocity regions where an acoustic velocity is higher than that in the edge regions are able to be provided in the outer side portions of the edge regions. Accordingly, the occurrence of the transverse mode is able to be more effectively reduced or prevented.

In an elastic wave device according to a preferred embodiment of the present invention, the mass addition film is not provided in the outer side region of the first edge region and the outer side region of the second edge region in the direction in which the first electrode fingers and the second electrode fingers extend. Also in this case, high acoustic velocity regions where an acoustic velocity is higher than that in the edge regions are able to be easily provided in the outer side portions of the edge regions. Accordingly, the occurrence of the transverse mode is able to be more effectively reduced or prevented.

In an elastic wave device according to a preferred embodiment of the present invention, a thickness of the mass addition film over the outer side region of the first edge region and the outer side region of the second edge region is smaller than or equal to a thickness of the mass addition film over the center region in the direction in which the first electrode fingers and the second electrode fingers extend. In this case, high acoustic velocity regions are able to be provided in the outer side portions of the edge regions. The occurrence of the transverse mode is able to be more effectively reduced or prevented.

In an elastic wave device according to a preferred embodiment of the present invention, the mass addition film includes a material with a density higher than that of a dielectric in the first dielectric layer. The mass addition film preferably includes a metal, for example.

In an elastic wave device according to a preferred embodiment of the present invention, the mass addition film includes a dielectric with a density higher than that of a dielectric in the first dielectric layer.

In an elastic wave device according to a preferred embodiment of the present invention, a second dielectric layer is further provided on the mass addition film.

In an elastic wave device according to a preferred embodiment of the present invention, the second dielectric layer includes a same material as the first dielectric layer. In this case, the number of types of dielectric materials is able to be reduced. In addition, the complication of a manufacturing process is not likely to occur.

In an elastic wave device according to a preferred embodiment of the present invention, a top surface of the second dielectric layer is flat or substantially flat. In this case, on the second dielectric layer, for example, a third dielectric layer including a flat or substantially flat surface is able to be provided.

In an elastic wave device according to a preferred embodiment of the present invention, a third dielectric layer laminated on the second dielectric layer is further provided.

In an elastic wave device according to a preferred embodiment of the present invention, the mass addition film is continuously provided from one end to the other end of a region in the IDT electrode where the first electrode fingers and the second electrode fingers are interdigitated with each other in the elastic wave propagation direction. In this case, the mass addition film is able to be easily provided.

Elastic wave devices according to the preferred embodiments of present invention are each able to easily provide a difference in an acoustic velocity in a center region and edge regions.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1A is a plan view of an elastic wave device according to a first preferred embodiment of the present invention excluding a mass addition film and second and third dielectric layers, and FIG. 1B is a cross-sectional view of the elastic wave device taken along line I-I of FIG. 1A which illustrates a structure in which the mass addition film and the second and third dielectric layers are laminated.

FIG. 2 is a schematic plan view of an elastic wave device according to the first preferred embodiment of the present invention which describes an acoustic velocity difference in an IDT electrode.

FIG. 3 is a partially cut-out plan view of an elastic wave device according to the first preferred embodiment of the present invention which illustrates a structure in which a mass addition film is provided on a first dielectric layer.

FIG. 4 is a cross-sectional view of an elastic wave device that is a comparative example.

FIG. 5 is a diagram illustrating a relationship between an edge region width and each of an electromechanical coupling coefficient in a third or higher order transverse mode and an electromechanical coupling coefficient of a fundamental wave, that is, in a primary mode in an elastic wave device according to a preferred embodiment of the present invention.

FIG. 6 is a diagram illustrating a relationship between an edge region width and each of an electromechanical coupling coefficient in a third or higher order transverse mode and an electromechanical coupling coefficient of a fundamental wave, that is, in a primary mode in an elastic wave device that is a comparative example.

FIG. 7 is a partially cut-out elevational cross-sectional view of a main portion of an elastic wave device according to a second preferred embodiment of the present invention.

### DETAILED DESCRIPTION OF THE PREFERRED EMBODIMENTS

Preferred embodiments of the present invention will be described in detail below with reference to the accompanying drawings.

It is to be noted that the preferred embodiments described in this specification are merely illustrative and the configurations described below may be partly replaced or combined between the different preferred embodiments.

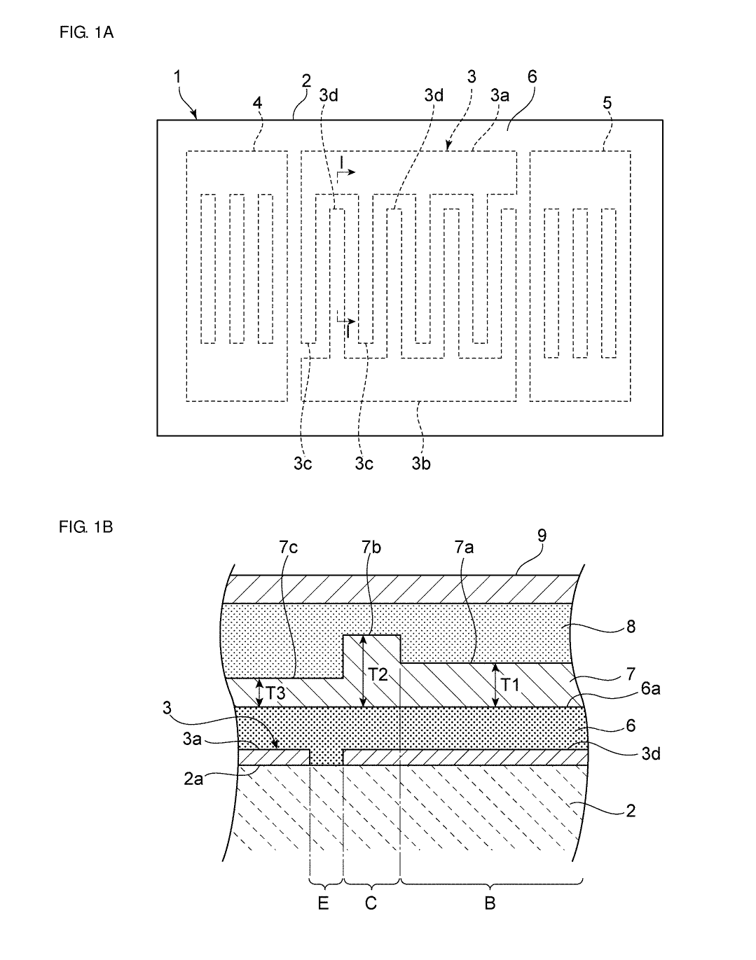

FIG. 1A is a plan view of an elastic wave device according to a first preferred embodiment of the present invention excluding a mass addition film and second and third dielectric layers. FIG. 1B is a cross-sectional view of the elastic wave device taken along line I-I of FIG. 1A which illustrates a structure in which the mass addition film and the second and third dielectric layers are laminated.

An elastic wave device 1 includes a piezoelectric substrate 2. The piezoelectric substrate 2 preferably includes, for example, piezoelectric monocrystal such as LiNbO₃ or LiTaO₃. The piezoelectric substrate 2 may include a structure in which a piezoelectric film is laminated on a support substrate that includes material with no piezoelectricity.

An IDT electrode 3 is provided on a top surface 2a of the piezoelectric substrate 2. A reflector 4 is provided on one side of the IDT electrode 3 and a reflector 5 is provided on the other side of the IDT electrode 3 in an elastic wave propagation direction. A first dielectric layer 6 is provided to cover the IDT electrode 3 and the reflectors 4 and 5. As illustrated in FIG. 1B, on the first dielectric layer 6, a mass addition film 7, a second dielectric layer 8, and a third dielectric layer 9 are laminated. In the plan view in FIG. 1A, the mass addition film 7, the second dielectric layer 8, and the third dielectric layer 9 are not illustrated.

The IDT electrode 3 includes a first busbar 3a and a second busbar 3b located opposite to the first busbar 3a. One ends of a plurality of first electrode fingers 3c are electrically connected to the first busbar 3a. One ends of a plurality of second electrode fingers 3d are electrically connected to the second busbar 3b. The first electrode fingers 3c and the second electrode fingers 3d are interdigitated with each other. In the reflectors 4 and 5, both ends of a plurality of electrode fingers are short-circuited.

The elastic wave device 1 is preferably, for example, a one-port elastic wave resonator including the IDT electrode 3 and the reflectors 4 and 5. An elastic wave device according to the first preferred embodiment of the present invention does not necessarily include a one-port elastic wave resonator, and may include another elastic wave device, such as a longitudinally coupled elastic wave filter.

The IDT electrode 3 and the reflectors 4 and 5 include appropriate metal(s). Examples of such metal (s) include Au, Pt, Cu, W, Mo, and an AlCu alloy.

The IDT electrode 3 and the reflectors 4 and 5 may preferably include, for example, a laminated metal film provided by laminating a plurality of metal films. The first dielectric layer 6 preferably includes, for example, silicon oxide. The first dielectric layer 6 covers the IDT electrode 3 and the reflectors 4 and 5. As illustrated in FIG. 1B, a top surface 6a of the first dielectric layer 6 is flat or substantially flat.

A dielectric in the first dielectric layer 6 is not limited to silicon oxide, and may be another dielectric, such as silicon oxynitride or silicon nitride, for example. In a case where the first dielectric layer 6 includes silicon oxide or silicon oxynitride, frequency temperature behavior is able to be improved.

The mass addition film 7 includes a material with a density higher than that of a material for the first dielectric layer 6. In the first preferred embodiment, the mass addition film 7 preferably includes metal(s). As the metal(s), for example, a high-density metal, such as titanium or Cu is preferably included. The mass addition film 7 may include a dielectric. In the case of a dielectric, the dielectric preferably has a density higher than that of a material of the first dielectric layer 6.

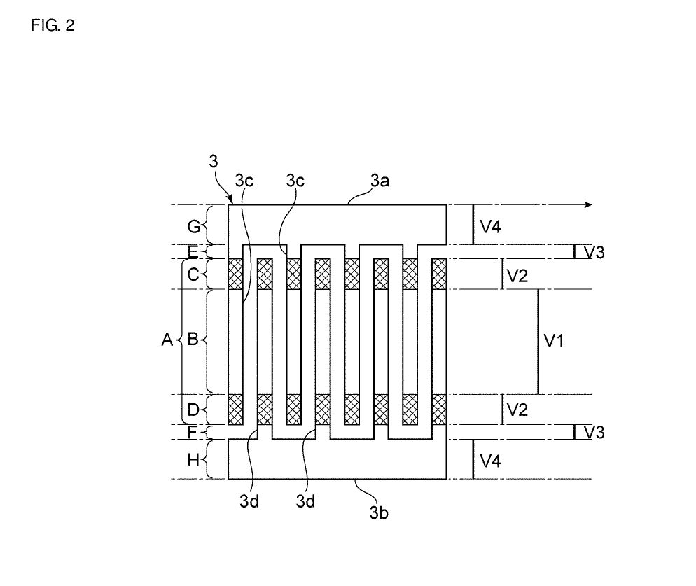

The mass addition film 7 includes a first portion 7a, a second portion 7b, and a third portion 7c which have different thicknesses. As illustrated in FIG. 2, in the IDT electrode 3, a region where the first electrode fingers 3c and the second electrode fingers 3d overlap as viewed from the elastic wave propagation direction is an intersection region A. In the first preferred embodiment, the intersection region A includes a center region B located at the center in a direction in which the first electrode fingers 3c and the second electrode fingers 3d extend, a first edge region C located on one side of the center region B, and a second edge region D located on the other side of the center region B.

A first high acoustic velocity region E is provided in an outer side portion of the first edge region C in the direction in which the first electrode fingers 3c and the second electrode fingers 3d extend. A second high acoustic velocity region F is provided in an outer side portion of the second edge region D. A third low acoustic velocity region G is provided in an outer side portion of the first high acoustic velocity region E in the direction in which the first electrode fingers 3c and the second electrode fingers 3d extend. A fourth low acoustic velocity region H is similarly provided in an outer side portion of the second high acoustic velocity region F. The first edge region C and the second edge region D are low acoustic velocity regions where an acoustic velocity is lower than that in the center region B. Accordingly, the first edge region C and the second edge region D correspond to a first low acoustic velocity region and a second low acoustic velocity region, respectively. The low acoustic velocity regions G and H are therefore called the third low acoustic velocity region G and the fourth low acoustic velocity region H, respectively.

In order to provide the piston mode, acoustic velocities V1 to V4 illustrated in FIG. 2 are set in these regions. The acoustic velocities V1 to V4 are illustrated on the right side of FIG. 2, and the acoustic velocity increases toward the right side as represented by an arrow. That is, the acoustic velocity relationship of V3>V1>V2>V4 is established. In the third low acoustic velocity region G and the fourth low acoustic velocity region H, the first busbar 3a and the second busbar 3b are provided, respectively. Accordingly, in these regions, the acoustic velocity is the lowest.

Referring back to FIG. 1B, the film thickness of the first portion 7a, the film thickness of the second portion 7b, and the film thickness of the third portion 7c are defined as T1, T2, and T3, respectively. The relationship of T2>T1>T3 is established.

The acoustic velocities in the center region B, the first edge region C, the second edge region D, the first high acoustic velocity region E, and the second high acoustic velocity region F are adjusted by adjusting the arrangement of the first electrode fingers 3c and the second electrode fingers 3d as viewed from the elastic wave propagation direction and the thickness of the mass addition film 7.

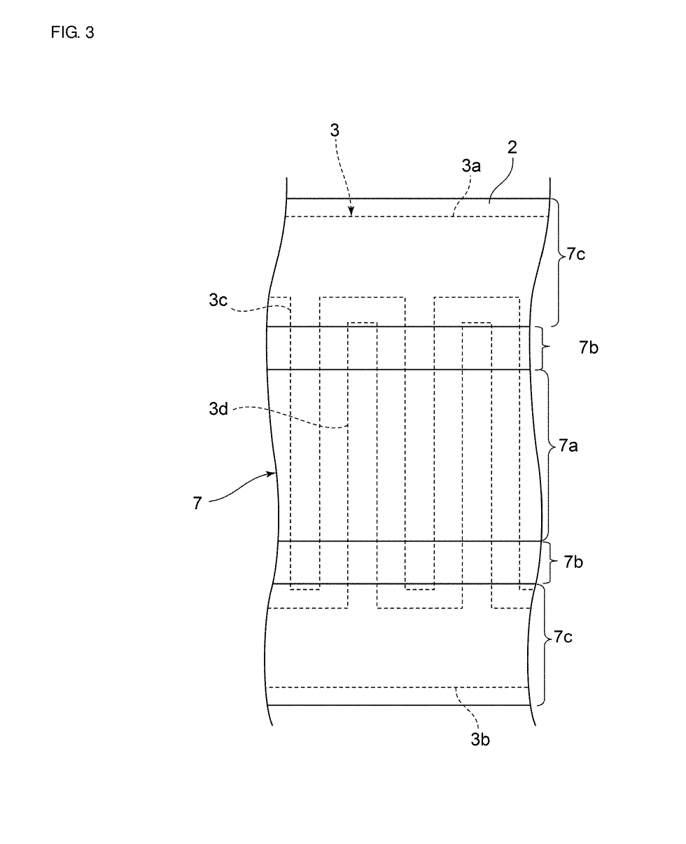

The second portion 7b of the mass addition film 7 is provided in portions over the first edge region C and the second edge region D which are hatched in FIG. 2. Although only the portions over the first electrode fingers 3c and the second electrode fingers 3d are hatched in FIG. 2, the mass addition film 7 is actually present between the first electrode finger 3c and the second electrode finger 3d in the elastic wave propagation direction as illustrated in FIG. 3. That is, in the region where the first electrode fingers 3c and the second electrode fingers 3d are interdigitated with each other, the mass addition film 7 is continuously provided from one end to the other end of the region in the elastic wave propagation direction.

The second portion 7b is provided over the first electrode fingers 3c and the second electrode fingers 3d in the first edge region C and the second edge region D illustrated in FIG. 2. The first portion 7a is provided over the IDT electrode 3 in the center region B. The third portion 7c is provided to extend from a portion over the first high acoustic velocity region E to a portion over the third low acoustic velocity region G and extend from a portion over the second high acoustic velocity region F to a portion over the fourth low acoustic velocity region H. The third portion 7c does not necessarily reach the portion over the third low acoustic velocity region G and the portion over the fourth low acoustic velocity region H.

Since the mass addition film 7 including portions of three film thicknesses is provided as described above, the acoustic velocity relationship of V3>V1>V2>V4 is established as illustrated in FIG. 2.

The acoustic velocity V2 in the first edge region C and the second edge region D is lower than the acoustic velocity V1 in the center region B. The first high acoustic velocity region E is provided in the outer side portion of the first edge region C, and the second high acoustic velocity region F is provided in the outer side portion of the second edge region D. Accordingly, in the piston mode, the occurrence of the transverse mode is able to be significantly reduced or prevented.

The above-described acoustic velocity differences are able to be obtained only by providing one type of material layer, that is, the mass addition film 7 after providing the IDT electrode 3. Accordingly, acoustic velocity differences are able to be easily obtained by performing patterning or film formation using a mask to form the mass addition film 7.

As illustrated in FIG. 1B, the second dielectric layer and the third dielectric layer 9 are laminated on the mass addition film 7. However, the second dielectric layer 8 and the third dielectric layer 9 are not necessarily provided. The second dielectric layer 8 preferably includes an appropriate dielectric material, such as silicon oxide or silicon oxynitride, for example. The second dielectric layer 8 preferably includes the same material as the first dielectric layer 6, for example. In this case, the complication of a manufacturing process is not likely to occur. In addition, the number of types of materials is able to be reduced.

The top surface of the second dielectric layer 8 is flat or substantially flat. Accordingly, in a case where the film formation of the third dielectric layer 9 is performed using a suitable deposition method, the top surface of the third dielectric layer 9 also becomes flat or substantially flat. The top surfaces of the second dielectric layer 8 and the third dielectric layer 9 are preferably flat or substantially flat. In this case, the variations in characteristics is able to be reduced.

In the first preferred embodiment, the third dielectric layer 9 preferably includes silicon nitride, for example. As a result, the structure under the second dielectric layer 8 is protected. By adjusting the film thickness of the third dielectric layer 9, the adjustment of a frequency is able to be performed. That is, the third dielectric layer 9 may be a frequency adjustment film. Another dielectric other than silicon nitride, such as silicon oxynitride or alumina, for example, may be included.

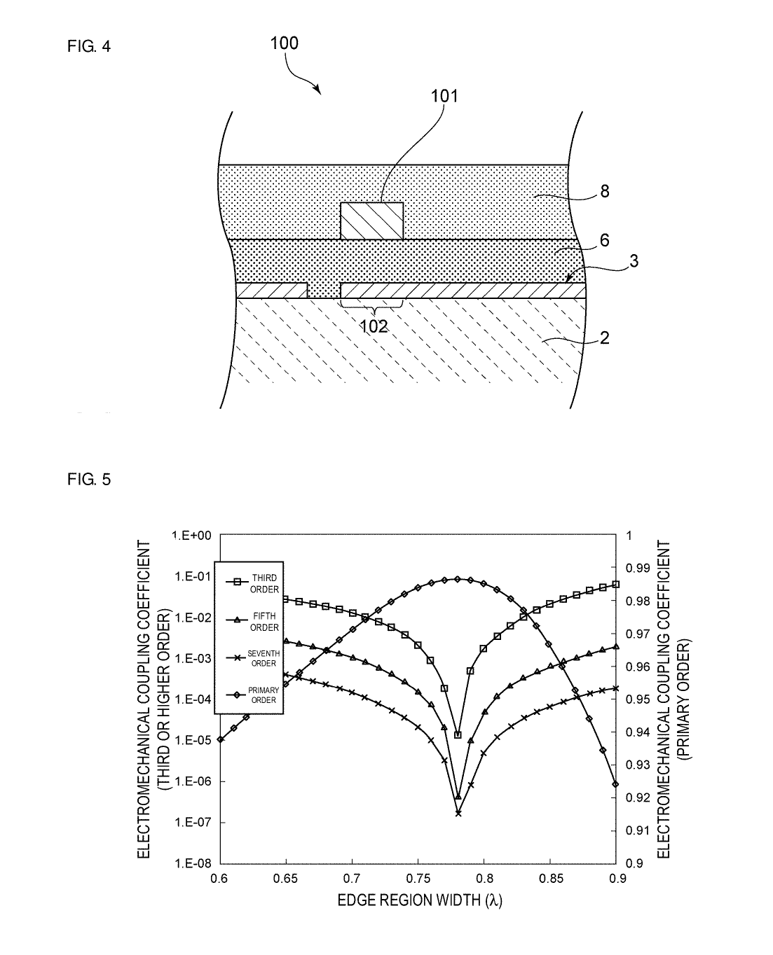

The elastic wave device 1 according to the first preferred embodiment and an elastic wave device that is a comparative example including a structure illustrated in FIG. 4 were created. A structure according to the first preferred embodiment is as follows.
The piezoelectric substrate 2: a LiNbO₃ substrate.
Electrode structure of the IDT electrode 3 and the reflectors 4 and 5: the laminated structure of Ti, Al, Ti, Pt, and NiCr from the top. The thicknesses of these films are Ti film=about 10 nm, Al film=about 130 nm, Ti film=about 10 nm, Pt film=about 30 nm, and NiCr film=about 10 nm.
The duty in the IDT electrode 3 was set to about 0.5, and a wavelength λ determined in accordance with an electrode finger pitch was set to about 2 μm.
The first dielectric layer 6: a layer including silicon oxide and having a thickness of about 0.2 μm.
The second dielectric layer 8: a layer including silicon oxide and having a thickness of about 0.31 μm.
The mass addition film 7: a film including titanium. The film thickness T1 of the first portion 7a=about 0.14 μm, the film thickness T2 of the second portion 7b=about 0.21 μm, and the film thickness T3 of the third portion 7c=about 0.1 μm.
The third dielectric layer 9 was not provided.

In the comparative example, only in an edge region 102, a mass addition film 101 was provided on the first dielectric layer as illustrated in FIG. 4. The mass addition film 101 is a titanium strip extending in the elastic wave propagation direction in the edge region 102. The thickness of the mass addition film 101 was set to about 0.1 μm. In the comparative example, no mass addition film was provided over the center region, the high acoustic velocity regions, and the busbars. The other structure is the same as or similar to the structure of the first preferred embodiment.

In the elastic wave device according to the first preferred embodiment and the elastic wave device that is a comparative example, an electromechanical coupling coefficient in the primary mode, that is, the fundamental mode and an electromechanical coupling coefficient in a third or higher order transverse mode were determined by applying finite element analysis. In the first preferred embodiment and the comparative example, the above electromechanical coupling coefficients were determined while changing the width of the edge region.

FIG. 5 is a diagram illustrating a relationship between an edge region width and each of an electromechanical coupling coefficient in a primary mode and an electromechanical coupling coefficient in a third or higher order transverse mode in an elastic wave device according to the first preferred embodiment.

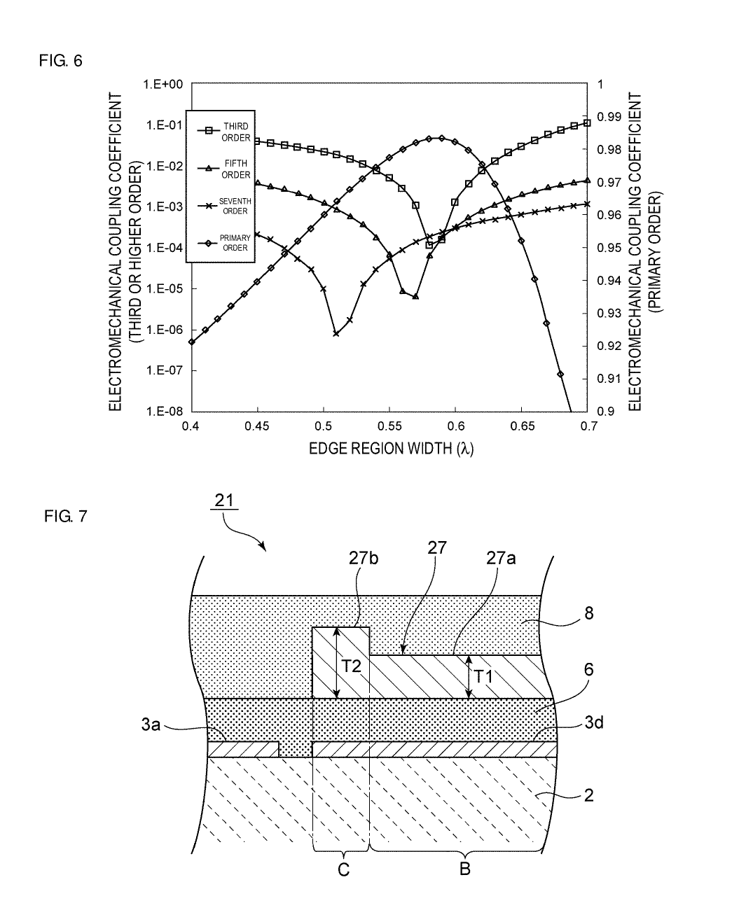

FIG. 6 is a diagram illustrating a relationship between an edge region width and each of an electromechanical coupling coefficient of a fundamental wave (in a primary mode) and an electromechanical coupling coefficient in a third or higher order transverse mode in an elastic wave device that is the above comparative example. In an elastic wave device, the electromechanical coupling coefficient of a fundamental wave is preferably large. As illustrated in FIG. 6, in the comparative example, in the range of an edge region width from about 0.55λ to about 0.63λ in which the electromechanical coupling coefficient of a fundamental wave is large, the electromechanical coupling coefficient in the third-order transverse mode is very large and the electromechanical coupling coefficient in the fifth-order transverse mode and the electromechanical coupling coefficient in the seventh-order transverse mode are relatively large.

In contrast, as illustrated in FIG. 5, in the first preferred embodiment, in the range of an edge region width from about 0.75λ to about 0.8λ in which the electromechanical coupling coefficient of a fundamental wave is large, all of the electromechanical coupling coefficient in the third-order transverse mode, the electromechanical coupling coefficient in the fifth-order transverse mode, and the electromechanical coupling coefficient in the seventh-order transverse mode are small. In particular, near the range of an edge region width from about 0.77λ to about 0.78λ, curves representing the electromechanical coupling coefficients in the third-order transverse mode, the fifth-order transverse mode, and the seventh-order transverse mode show the minimum values. Accordingly, in a case where an edge region width is set to fall within the range of about 0.77λ to about 0.78λ, the occurrence of a high-order transverse mode is able to be significantly reduced or prevented and the high electromechanical coupling coefficient of a fundamental wave is able to be provided. It is therefore apparent that an elastic wave device with excellent characteristics is able to be provided.

FIG. 7 is a partially cut-out elevational cross-sectional view of a main portion of an elastic wave device according to a second preferred embodiment of the present invention. In an elastic wave device 21 according to the second preferred embodiment, a mass addition film 27 includes a first portion 27a and a second portion 27b and does not include the third portion 7c illustrated in FIG. 1B. Also in this case, an acoustic velocity difference is able to be obtained only by providing portions of two film thicknesses at the time of the formation of the mass addition film 27. That is, the acoustic velocity in the first edge region C is able to be much lower than that in the center region B. Thus, a mass addition film is not necessarily provided over the first high acoustic velocity region and the second high acoustic velocity region.

In the preferred embodiments of the present invention, in order to provide the piston mode, the mass addition film may include portions of at least two film thicknesses as described above. In the first edge region and the second edge region, the mass addition film may have the greatest thickness.

Accordingly, although the film thickness T1 of the first portion 7a is larger than the film thickness T3 of the third portion 7c in FIG. 1B, the film thickness T1 and the film thickness T3 may be equal or substantially equal. The film thickness T3 of the third portion 7c may be less than or equal to the film thickness T1 of the first portion 7a.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An elastic wave device comprising:
a piezoelectric substrate;
an IDT electrode provided on the piezoelectric substrate;
a first dielectric layer covering the IDT electrode; and
a mass addition film provided on the first dielectric layer and including portions of at least two different thicknesses; wherein
the IDT electrode includes a first busbar, a second busbar opposed to the first busbar, a plurality of first electrode fingers that each include one end electrically connected to the first busbar, and a plurality of second electrode fingers that each include one end electrically connected to the second busbar;
the first electrode fingers and the second electrode fingers are interdigitated with each other; and
an intersection region where the first electrode fingers and the second electrode fingers overlap each other, as viewed from an elastic wave propagation direction, includes a center region, a first edge region located on one side of the center region in a direction in which the first electrode fingers and the second electrode fingers extend, and a second edge region located on another side of the center region in the direction in which the first electrode fingers and the second electrode fingers extend.

2. The elastic wave device according to claim 1, wherein a thickness of the mass addition film in portions corresponding to the first edge region and the second edge region is larger than a thickness of the mass addition film in a portion corresponding to the center region.

3. The elastic wave device according to claim 1, wherein
the mass addition film extends to an outer side region of the first edge region and an outer side region of the second edge region in the direction in which the first electrode fingers and the second electrode fingers extend; and
a thickness of the mass addition film over the outer side region of the first edge region and the outer side region of the second edge region is less than a thickness of the mass addition film over the first edge region and the second edge region.

4. The elastic wave device according to claim 1, wherein the mass addition film is not provided in an outer side region of the first edge region and an outer side region of the second edge region in the direction in which the first electrode fingers and the second electrode fingers extend.

5. The elastic wave device according to claim 2, wherein a thickness of the mass addition film over an outer side region of the first edge region and an outer side region of the second edge region is less than or equal to a thickness of the mass addition film over the center region in the direction in which the first electrode fingers and the second electrode fingers extend.

6. The elastic wave device according to claim 1, wherein the mass addition film includes a material with a density higher than that of a dielectric in the first dielectric layer.

7. The elastic wave device according to claim 6, wherein the mass addition film includes a metal.

8. The elastic wave device according to claim 6, wherein the mass addition film includes a dielectric with a density higher than that of a dielectric in the first dielectric layer.

9. The elastic wave device according to claim 1, further comprising a second dielectric layer provided on the mass addition film.

10. The elastic wave device according to claim 9, wherein the second dielectric layer includes a same material as the first dielectric layer.

11. The elastic wave device according to claim 9, wherein a top surface of the second dielectric layer is flat or substantially flat.

12. The elastic wave device according to claim 9, further comprising a third dielectric layer laminated on the second dielectric layer.

13. The elastic wave device according to claim 1, wherein the mass addition film is continuously provided from one end to another end of a region in the IDT electrode where the first electrode fingers and the second electrode fingers are interdigitated with each other in the elastic wave propagation direction.

14. The elastic wave device according to claim 1, further comprising a reflector provided on one side of the IDT electrode in the elastic wave propagation direction.

15. The elastic wave device according to claim 14, wherein the first dielectric layer covers the reflector.

16. The elastic wave device according to claim 1, wherein the mass addition film that includes portions of at least three different thicknesses.

17. The elastic wave device according to claim 16, wherein
the mass addition film that includes a first portion provided over the IDT electrode in the center region, a second portion provided over the first electrode fingers and the second electrode fingers, and a third portion provided over the first and second edge regions;
a thickness of the second portion is greater than a thickness of the first portion; and
a thickness of the third portion is less than the thickness of the first portion.

18. The elastic wave device according to claim 12, wherein the third dielectric layer includes silicon nitride.

19. The elastic wave device according to claim 12, wherein the third dielectric layer is a frequency adjustment film.
